(19) United States
(12) Patent Application Publication
(10) Pub. No.: US 2023/0341483 A1
(43) Pub. Date: Oct. 26, 2023

(54) Dual mode technique based on Hall effect and induction for magnetic field sensors

(71) Applicants: The Board of Trustees of the Leland Stanford Junior University, Stanford, CA (US); The Board of Trustees of the University of Arkansas, Little Rock, AR (US)

(72) Inventors: Anand Vikas Lalwani, Palo Alto, CA (US); Debbie G. Senesky, Oakland, CA (US); Avidesh F. Marajh, Chaguanas (TT); Satish Shetty, Fayetteville, AR (US); Gregory J. Salamo, Fayetteville, AR (US); H. Alan Mantooth, Fayetteville, AR (US)

(21) Appl. No.: 18/137,971

(22) Filed: Apr. 21, 2023

Related U.S. Application Data
(60) Provisional application No. 63/333,752, filed on Apr. 22, 2022.

(51) Int. Cl. G01R 33/07

(52) U.S. Cl. CPC G01R 33/075

(57) ABSTRACT

Improved magnetic field sensing is provided by switching between a Hall effect mode and an inductive mode. The inductive mode is used when the frequency of the magnetic field being sensed is above a frequency threshold. The Hall effect mode is used when the frequency of the magnetic field is below the frequency threshold. The sensor element can be any Hall effect sensor element. In the Hall effect mode, the sensor element is used conventionally, optionally including refinements such as current spinning for more accurate results. In the inductive mode, no current is provided to the sensor element. The resulting transverse sensor voltage is induced by time-variation of the magnetic field, and can be used as a measure of magnetic field strength.

### CROSS REFERENCE TO RELATED APPLICATIONS

This application claims priority from U.S. Provisional Patent Application 63/333,752 filed Apr. 22, 2022, which is incorporated herein by reference.

### GOVERNMENT SPONSORSHIP

This invention was made with Government support under contract 1449548 awarded by the National Science Foundation. The Government has certain rights in the invention.

### FIELD OF THE INVENTION

This invention relates to magnetic field sensing at non-zero frequency.

### BACKGROUND

As power electronics become smaller, operation at higher frequencies tends to be desired. To be able to monitor the magnetic field (and therefore provide diagnostics) of the system, Hall-effect sensors have historically been used. However, Hall-effect sensors are optimal at low frequencies and due to limitations of current spinning, cannot measure magnetic field at high frequencies.

The reasons for this can be better appreciated by considering the following formula for the Hall voltage V_{H} resulting from a sinusoidal magnetic field B₀ sin(ωt):

$${V}_{H} = \frac{I ( {B}_{0} sin ( ω t ) + α )}{q {n}_{s}} + β ω {B}_{0} cos ( ω t ) . \qquad ( 1 )$$

Here I is the current through the sensor, B₀ is the amplitude of the magnetic field, ω is the angular frequency of the magnetic field, q is the electronic charge, and nₛ is the sheet density of the Hall effect sensor. Ideally, the Hall voltage is just IB₀/qnₛ, so Eq. 1 includes the effects of two non-idealities—DC offset (parametrized by α) and inductance (parametrized by β). The coefficients α and β depend on sensor geometry and composition. Current spinning as mentioned above amounts to driving current through a Hall sensor such that the effect of DC offset and inductance on the Hall voltage is minimized (ideally, eliminated) in the resulting Hall signal (e.g., by adding Hall signals from out of phase currents and the like). Several versions of current spinning are known in the art.

However, modern techniques to enable high frequency Hall-effect sensing via current spinning tend to be complex and require significant electronics to get rid of the undesired DC offset and induced signals. Thus, there is a clear need shown by industry and literature for a single Hall-effect sensor to be able to operate from DC to very high frequencies (e.g., tens of MHz or more) without such complexities at high frequencies.

### SUMMARY

The fundamental problem with AC magnetic field measurement is that AC magnetic fields induce a voltage into the Hall-effect sensor (i.e., the second term in Eq. 1). Techniques such as the dual Hall plate can be used to remove this induced voltage. Alternatively, current spinning techniques on the signal processing side can be used. What we noticed is that above a critical frequency (depending on the architecture of the Hall-effect sensor and bias current) it is more beneficial to “turn off” the Hall-effect sensor (and thus get rid of the DC offset term) and just rely on the induced frequency to back out the magnetic field strength. A simple microcontroller (generally already attached to the Hall-effect sensor) is the only tool required and algorithmically we can back out the frequency of the magnetic field and use the frequency to then back out the magnetic field strength. Using a 2 DEG (2D electron gas) Hall-effect sensor as an inductor pick up in this approach has specific advantages listed below.

Thus an exemplary embodiment is a magnetic field sensor including:
1) a sensor element having a Hall sensing mode with a Hall signal output, where the sensor element can also operate in an inductive sensing mode to inductively sense magnetic field; and
2) a controller configured to automatically select between the Hall sensing mode and the inductive sensing mode according to a frequency of a magnetic field being sensed. The automatic selection criteria frequency (toggle frequency) typically depends on the geometry of the Hall-effect sensor (as seen in the examples below). Preferably, the toggle frequency is where the sensitivity of the Hall-effect sensor, i.e. the voltage measured for every increment in the magnetic field strength, is greater for passive inductive sensing than active biased sensing. The toggle frequency depends solely on bias conditions and geometry of the Hall-effect sensor. The toggle frequency can also be calculated using linear regression if the Hall-effect sensor geometry is unknown.

Applications include systems where the magnetic field frequency is either beyond current spinning (100 s KHz) or has a wide range (from DC/low frequencies to high frequencies). Some such applications include turbines, motors, DC-DC converters, inverters and engines. We believe the technique described here will be likely to provide better results for diagnosing health of motor systems using Hall-effect systems than prior approaches.

Advantages include:
1. Ultra-wide frequency range (DC to tens or hundreds of MHz).
2. Lower cost—fewer circuits needed.
3. At DC it provides high sensitivity and low noise, relying on existing techniques like current spinning. Only when AC signal is higher than current spinning, do we switch from sensor being on to the sensor being off and being passive.
4. 2 DEG have very high mobility (e.g. GaAs/AlGaAs) compared to metals that are used for inductors. High mobility allows for higher frequency detection.
5. Temperature compensation. Dual systems with a coil+Hall-effect sensor suffer from temperature mismatch where, as temperature changes, the coil (being a different material) has different temperature compensation than the Hall sensor. The dual material systems require significantly more electronics for temperature compensation and each system requires individual circuitry.
6. Passive mode allows lower energy consumption

### BRIEF DESCRIPTION OF THE DRAWINGS

FIG. 1 shows an exemplary prior art Hall-effect sensor.

FIG. 2 shows an exemplary magnetic field sensor according to an embodiment of the invention.

FIG. 3 schematically shows an experimental apparatus for the measurements of FIGS. 5-6.

FIG. 4 schematically shows several different sensor geometries for the measurements of FIGS. 5-6.

FIG. 5 shows an example of the sensitivity of inductive sensing vs. frequency for several different sensor geometries, compared to Hall-mode sensitivity.

FIG. 6 shows an example of dependence of inductive sensitivity on sensor geometry.

### DETAILED DESCRIPTION

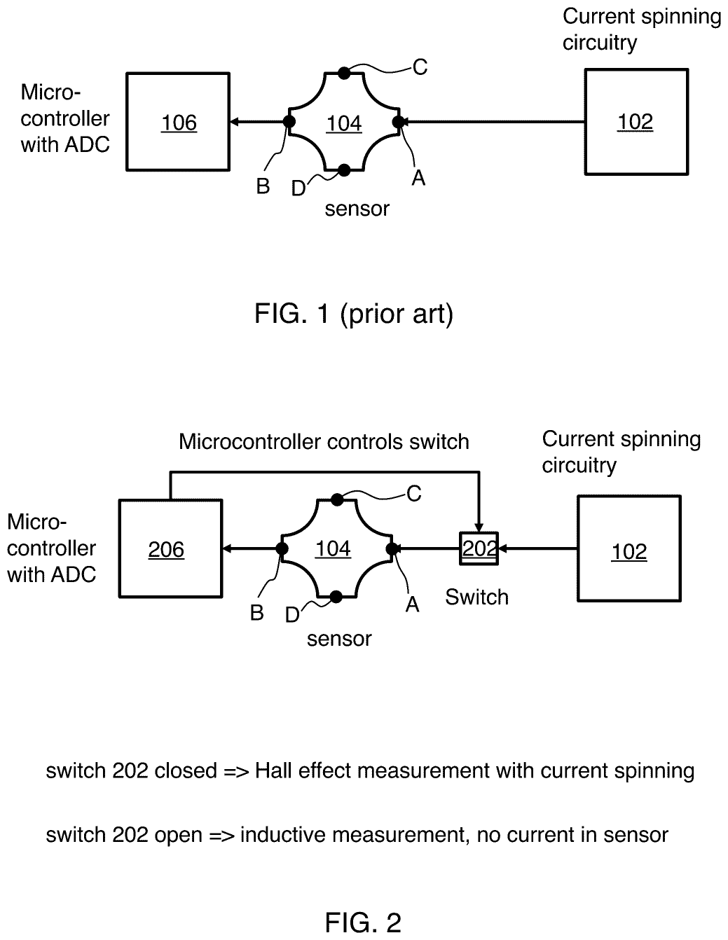

FIG. 1 shows an exemplary prior art Hall-effect sensor. Here 102 is the current spinning circuitry that provides current to sensor 104. Microcontroller 106 receives signals from sensor 104 and controls current spinning circuitry 102 (this control connection to circuitry 102 is conventional, and is therefore not shown for simplicity). More specifically, current is driven though sensor 104 between points A and B, and the resulting Hall voltage is measured between points C and D. As indicated above, this Hall voltage is given by Eq. 1, where the first term is the Hall term and the second term is the inductive term. In conventional current spinning approaches, the current is driven in such a way that the undesired signals from DC offset (α) and induction (β) are canceled in signal processing.

As indicated above, such signal processing becomes ever more difficult to do as the frequency increases. FIG. 2 shows an exemplary embodiment of the invention that addresses this problem. A switch 202 is placed between current spinning circuitry 102 and sensor 104.

Microcontroller 206 on FIG. 2 is similar to microcontroller 106 on FIG. 1, except it has the added capability of controlling switch 202 according to the principles described herein.

In particular, for sufficiently high magnetic field frequency, microcontroller 206 opens switch 202 such that no current is provided to sensor 104. The resulting voltage between points C and D on sensor 104 is just the second term of Eq. 1 (i.e., only the inductive term).

Preferably, a frequency threshold is defined such that all frequencies above the threshold are “sufficiently high” as above. The frequency threshold can be defined as the frequency at which the Hall sensitivity (S_{H}) and the inductive sensitivity (S_{I}) are the same (i.e., S_{H}=S_{I}). The frequency threshold can also be defined as a frequency where the two sensitivities are close (e.g., 0.9≤S_{H}/S_{I}≤1.1 or the like), in case one mode or the other has practical advantages that suggest introducing such a bias. Thus, sensor 104 on FIG. 2 is operated in an inductive sensing mode (with no current provided to the sensor) for above-threshold frequencies, and is operated in a current-spinning Hall effect mode for below-threshold frequencies.

These two sensitivities can be read off from Eq. 1 as follows:

$${S}_{H} = \frac{I}{q {n}_{s}} \qquad ( 2 )$$

$${S}_{I} = β ω \qquad ( 3 )$$

Note that the Hall sensitivity S_{H} depends on the current bias I, and the inductive sensitivity S_{I} increases with frequency ω. For a given sensor, the threshold frequency (or the suitable threshold frequency range) can be determined using Eqs. 2 and 3 in the appropriate condition on S_{H} and S_{I} to solve for ω.

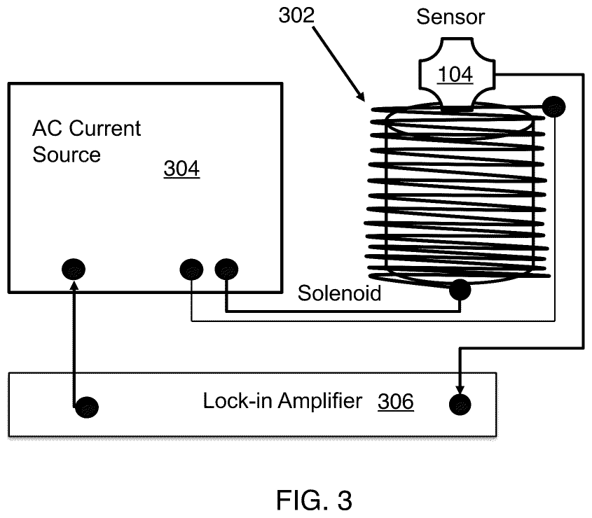

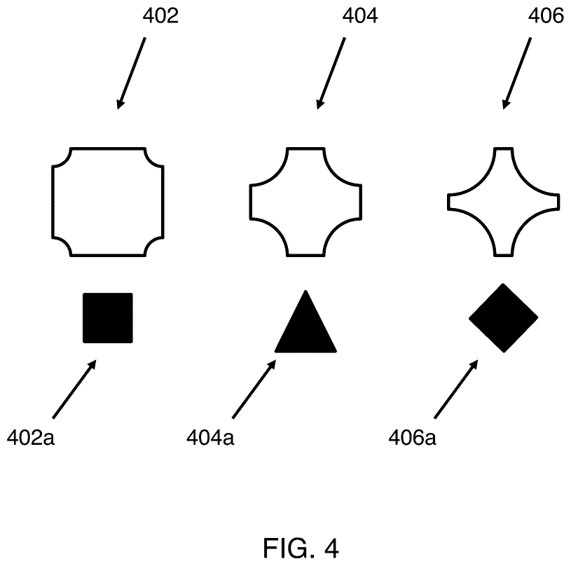

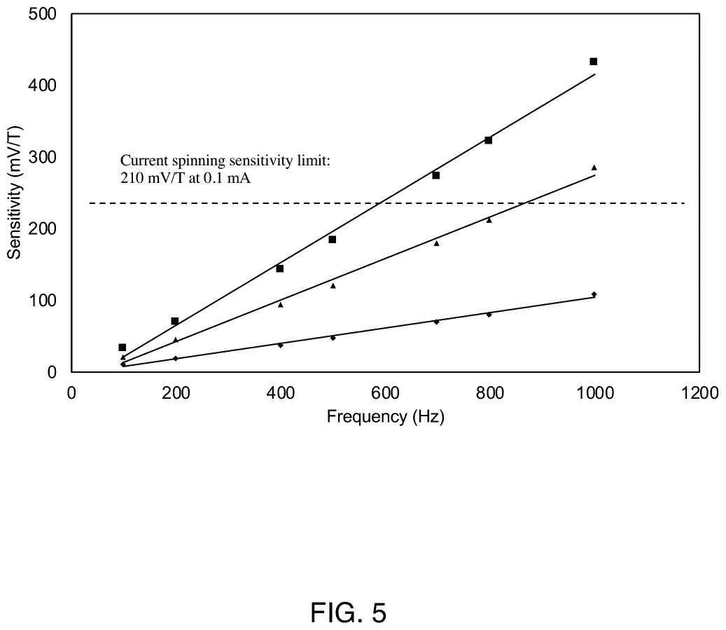

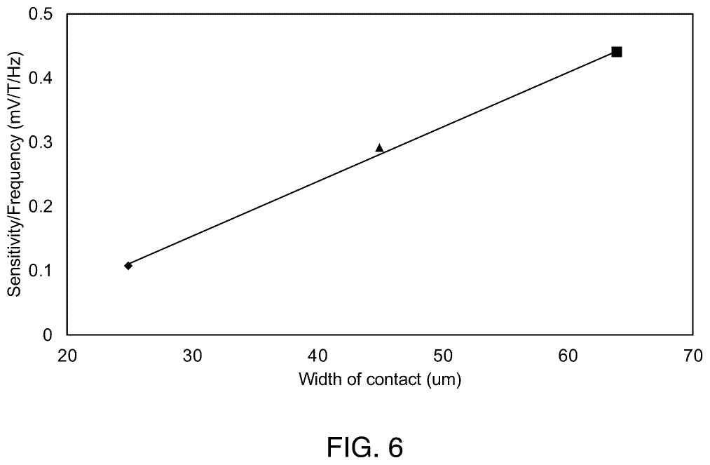

FIG. 3 schematically shows an experimental apparatus for the measurements of FIGS. 5-6. Here 304 is an AC current source driving a solenoid 302, and 306 is a lock-in amplifier configured to receive the Hall voltage from sensor 104.

FIG. 4 schematically shows several different sensor geometries for the measurements of FIGS. 5-6. Here 402, 404, 406 schematically show three different sensor geometries, and 402a, 404a, 406a are the corresponding symbols for the plots of FIGS. 5 and 6.

FIG. 5 shows an example of the sensitivity of inductive sensing vs. frequency for several different sensor geometries, compared to Hall-mode sensitivity. Here the dashed line is the Hall-mode sensitivity S_{H} (assuming a 0.1 mA bias current), and the plotted lines show inductive sensitivity S_{I} for the three sensor shapes of FIG. 4. As expected from the analysis above, the inductive sensitivity S_{I} is proportional to frequency, and the Hall sensitivity is frequency-independent. We also see that for sensor shape 402 on FIG. 4, the inductive sensitivity exceeds the Hall sensitivity for frequencies above roughly 600 Hz. For sensor shape 404 on FIG. 4, the inductive sensitivity exceeds the Hall sensitivity for frequencies above roughly 850 Hz. For sensor shape 406 on FIG. 4, the inductive sensitivity does not exceed the Hall sensitivity in the plotted frequency range, but it would if a larger frequency range were plotted.

FIG. 6 shows an example of dependence of inductive sensitivity on sensor geometry. This relates the sensitivities of FIG. 5 (in particular, the slopes of the plotted line) to sensor geometry (i.e., contact width). As indicated above, inductive sensitivity depends in general on the geometry and composition of the sensor.

Practice of the invention does not depend critically on details of sensor 104. Any conventional Hall sensor composition and geometry can be employed, such as silicon Hall sensors and 2 DEG (2-dimensional electron gas) Hall sensors.

1. A magnetic field sensor including:
a sensor element having a Hall sensing mode with a Hall signal output, wherein the sensor element can also operate in an inductive sensing mode to inductively sense magnetic field; and
a controller configured to automatically select between the Hall sensing mode and the inductive sensing mode according to a frequency of a magnetic field being sensed.

2. The magnetic field sensor of claim 1, wherein the Hall sensing mode includes measurement of a Hall voltage of the sensor element generated by a current through the sensor element, wherein the Hall voltage is proportional to a product of the current and the magnetic field.

3. The magnetic field sensor of claim 1, wherein the inductive sensing mode includes measurement of an induced voltage of the sensor element, wherein the induced voltage is proportional to a time derivative of the magnetic field.

4. The magnetic field sensor of claim 1, wherein the controller is configured to switch to the inductive sensing mode when the frequency of the magnetic field is above a predetermined frequency threshold.

5. The magnetic field sensor of claim 4, wherein a sensitivity of the Hall sensing mode is equal to a sensitivity of the inductive sensing mode at the predetermined frequency threshold.

6. The magnetic field sensor of claim 4, wherein the predetermined frequency threshold is determined by a geometry and a composition of the sensor element.

7. The magnetic field sensor of claim 1, wherein the sensor element includes a two-dimensional electron gas.

8. The magnetic field sensor of claim 1, wherein an active material of the sensor element is silicon.
